(19) United States
(12) Patent Application Publication
(10) Pub. No.: US 2008/0274369 A1
(43) Pub. Date: Nov. 6, 2008

(54) Novel Ruthenium-Based Materials and Ruthenium Alloys, Their Use in Vapor Deposition or Atomic Layer Deposition and Films Produced Therefrom

(76) Inventors: Eal H. Lee, Millpitas, CA (US); Nicola Truong, Milipes, CA (US); Robert Prater, Los Altos, CA (US); Morales Diana, Veradala, WA (US)

Correspondence Address: BUCHALTER NEMER, 18400 VON KARMAN AVE., SUITE 800, IRVINE, CA, 92612, US

(21) Appl. No.: 11/911,954

(22) PCT Filed: Apr. 21, 2005
(86) PCT No.: PCT/US05/13663

§ 371 Date: Oct. 18, 2007

(51) Int. Cl. B32B 15/00; C22C 5/04; B32B 9/00; C23C 14/34

(52) U.S. Cl. 428/639; 420/462; 204/298.13; 428/660; 428/662; 428/663; 428/665

(57) ABSTRACT

An alloy for use in vapor deposition or atomic layer deposition is described herein that includes ruthenium and at least one element from group IV, V or VI of the Periodic Chart of the Elements or a combination thereof. In addition, a layered material is described herein that comprises at least one layer that includes a ruthenium-based material or ruthenium-based alloy and at least one layer that includes at least one element from group IV, V or VI of the Periodic Chart of the Elements or a combination thereof.

### FIELD OF THE INVENTION

The field of the invention is ruthenium-based materials and/or ruthenium alloys, their uses in vapor deposition and atomic layer deposition and layered materials and films formed and/or produced therefrom.

### BACKGROUND

Electronic and semiconductor components are used in ever increasing numbers of consumer and commercial electronic products, communications products and data-exchange products. Examples of some of these consumer and commercial products are televisions, computers, cell phones, pagers, palm-type organizers, portable radios, car stereos, or remote controls. As the demand for these consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the defects that are present or could be present in the larger component should be identified and corrected, if possible, before the component is scaled down for the smaller electronic products.

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as deposition of a metal or other compound—should be evaluated and, if possible, improved.

Increasing demand of microprocessor speed prompted a transition from aluminum to copper based interconnects, namely to reduce the electrical resistivity of circuitry. One of the impediments in copper (Cu) interconnects is Cu diffusion into the substrate. Traditionally, TaN/Ta or TiN/Ti bi-layer barrier films have been used for copper (Cu) diffusion barrier in microelectronic circuit fabrication. One of the drawbacks of these barrier schemes is inability to electroplate Cu directly on Ta or Ti. Thus, Cu-seed film is placed on the barrier film by physical vapor deposition (PVD) to facilitate copper electrochemical plating (ECP). As the feature size in interconnects becomes smaller, however, the composite thickness of barrier/Cu-seed layer is becoming too thick relative to via/trench size. Recently, ruthenium (Ru) has emerged as a potential barrier material because copper can be plated directly on Ru without PVD Cu-seed layer.

Although Ru has shown excellent barrier strength, its adhesion to substrate layer (Si and SiO₂) is found to be unacceptably poor. For example, ruthenium has a Ru—O bond strength of 43 Kcal/mol, as compared to Ru—C, which is 152 Kcal/mol; Ti—O, which is 168 Kcal/mol or Ta—O, which is 198 Kcal/mol. Adhesion is one of the most important factors in microelectronic interconnects because poorly bonded interfaces often increase the chances of device failures, especially those failures that are a result of stress and electromigration. In the past, Ru [1-3], Ru—RuO_{2 [}4], and RuTiN—RuTiO [5] have been suggested for diffusion barrier. However, these approaches have not been challenged by rigorous adhesion testing.

Therefore, it would be ideal to develop ruthenium-based materials and ruthenium-based alloy materials that can be used in vapor deposition and atomic layer deposition (ALD) techniques given its exceptional barrier strength. In addition, these ruthenium-based materials and ruthenium-based alloy materials should provide better adhesion than those already mentioned, they should lower electrical resistivity, they should provide better chemical mechanical polishing (CMP) compatibility with copper, they should lower particle generation, and provide for less preventive chamber maintenance. Also, it would be advantageous to produce films and layered materials from the ruthenium-based materials and/or ruthenium-based alloy materials.

### BRIEF DESCRIPTION OF THE FIGURES

FIG. 1 shows optical micrographs of hot rolled and annealed (a) Ta and (b) Ti-5 at. % Zr alloys.

FIG. 2 shows SEM images of via step coverage: TaN deposited in an ion metal plasma (IMP) chamber with a coarse grain Ta (50 μm) target and TiZrN deposited in a conventional Widebody chamber with fine grain Ti-5 at % Zr (10 μm) target.

FIG. 3 shows stress variation as a function of film thickness for (a) Cu on S₃N₄ and Ru on SiO₂. Square dots are the data points that failed the tape-pull test.

FIG. 4 shows stress variation as a function of substrate temperature for 20 nm thick (a) Ta and (b) TiZr films.

FIG. 5 shows stress variation as a function of substrate temperature for 20 nm-Ta/10 nm-Ru/1 μm-Cu and 20 nm-TiZr/10 nm-Ru/1 μm-Cu film stacks. The square dots represent the failed datapoints in the tape-pull test. Note: there are no failed data points in the second graph.

FIG. 6 shows the effects of temperature on stress for a ruthenium film.

FIG. 7 shows SEM cross-section micrographs for 20 nm-TaN/Cu and 20 nm-TiZrN/Cu stacks that were annealed at 750° C. for one hour.

FIG. 8 shows the RBS profile for (a) 27 nm-TaN/Cu and (b) 20 nm-TiZrN/Cu stacks that were annealed at 700° C. for one and five hours. The RBS spectra were taken after removing the protective Si₃N₄ and Cu layers.

FIG. 9 shows (a) TEM microstructure of 5 nm-TiZrN/Cu stack that was annealed at 650° C. for one hour and (b) SEM cross-sectional view of 25 nm-TiZr/Cu stack that was annealed at 550° C. for one hour.

FIG. 10 shows SEM cross-sectional view of 5 nm-Ru/Cu stacks that were annealed at (a) 700 and (b) 750° C. for one hour.

FIG. 11 shows SEM cross-section micrographs of (a, b) TiZr/Ru/Cu and (c, d) TiZrN/R/Cu stacks subjected to 550 and 650° C. for one hour, respectively.

FIG. 12 shows electrical resistivity variation as a function of film thickness for Ta, Ti, Ru, and Cu.

FIG. 13 shows resistivity variation as a function of deposition power for TaN and TiZrN films deposited at 400° C.

### SUMMARY OF THE SUBJECT MATTER

An alloy for use in vapor deposition or atomic layer deposition is described herein that includes ruthenium and at least one element from group IV, V or VI of the Periodic Chart of the Elements or a combination thereof.

In addition, a layered material is described herein that comprises at least one layer that includes a ruthenium-based material or ruthenium-based alloy and at least one layer that includes at least one element from group IV, V or VI of the Periodic Chart of the Elements or a combination thereof.

### DETAILED DESCRIPTION

Ruthenium-based materials and ruthenium-based alloy materials that can be used in vapor deposition or atomic layer deposition techniques have been developed and will be described herein. In addition, these ruthenium-based materials and ruthenium-based alloy materials provide better adhesion than those already mentioned, they lower electrical resistivity, they provide better chemical mechanical polishing (CMP) compatibility with Cu, they reduce particle generation, and provide for less preventive chamber maintenance, because they are non-nitriding processes. In addition, a layered material is described herein that comprises at least one layer that includes a ruthenium-based material or ruthenium-based alloy and at least one layer that includes at least one element from group IV, V or VI of the Periodic Chart of the Elements or a combination thereof.

In developing the ruthenium-based materials and ruthenium-based alloys that have been found to work in the previously mentioned deposition techniques and that meet the above-outlined goals, the following atom and atom-molecule bonds were found to be good: Ta—SiO₂, Ti—SiO₂, TiZr—SiO₂, Ta—Ru, Ti—Ru, TiZr—Ru, Ta—Cu, Ti—Cu, Zr—Cu, and Ru—Cu. Using this information, a set of new materials and alloys were developed comprising group IV, V and VI elements and their alloys with ruthenium, such as Ti—Ru, Zr—Ru, Hf—Ru, TiZr—Ru, V—Ru, Nb—Ru, Ta—Ru, Mo—Ru, W—Ru, etc. Based on this work, an alloy for use in vapor deposition or atomic layer deposition is described herein that includes ruthenium and at least one element from group IV, V or VI of the Periodic Chart of the Elements or a combination thereof. In addition, this work led to layered materials that comprise at least one layer that includes a ruthenium-based material or ruthenium-based alloy and at least one layer that includes at least one element from group IV, V or VI of the Periodic Chart of the Elements or a combination thereof. The layered material may also comprise at least one additional layer that comprises copper, a copper alloy or a combination thereof.

In contemplated embodiments, each of the at least one layer that includes a ruthenium-based material or ruthenium-based alloy is less than about 300 Å thick. In other embodiments, the at least one layer that includes a ruthenium-based material or ruthenium-based alloy is less than about 200 Å thick. And in yet other embodiments, the at least one layer that includes a ruthenium-based material or ruthenium-based alloy is less than about 150 Å thick. The same is true for the at least one layer that includes at least one element from the group IV, V or VI of the Periodic Chart of the Elements, wherein that layer or layers may each be less than about 300 Å thick, about 200 Å thick and/or less than about 150 Å thick.

Ruthenium concentration can be adjusted to control adhesion and Cu plating capability. TiZr and TiZrN can be compared with ruthenium to show the superiority of ruthenium and ruthenium-based alloys in these types of applications. For example, TiZr and TiZrN have shown good barrier strength against Cu diffusion up to 550° C. and 650° C., respectively, and Ru has shown excellent barrier strength up to 700° C. Most PVD metal films show compressive stress, but barrier-Cu composite films eventually become tensile, which weakens adhesion. On the other hand, PVD TiZr has low tensile stress and thus does not show a reversal in stress state when Cu is deposited. In particular, TiZr—Ru alloy is of great interest for barrier application, especially in view of its good adhesion and direct Cu plating capability. Apart from bi-layer barrier scheme, TiZr—Ru alloys allow for the preparation of films in a single deposition process.

Alloys and materials described herein may be used to form sputtering targets, and those targets contemplated herein comprise any suitable shape and size depending on the application and instrumentation used in the PVD process. Sputtering targets contemplated herein also comprise a surface material and a core material, wherein the surface material is coupled to the core material. The surface material is that portion of the target that is exposed to the energy source at any measurable point in time and is also that part of the overall target material that is intended to produce atoms that are desirable as a surface coating. As used herein, the term “coupled” means a physical attachment of two parts of matter or components (adhesive, attachment interfacing material) or a physical and/or chemical attraction between two parts of matter or components, including bond forces such as covalent and ionic bonding, and non-bond forces such as Van der Waals, electrostatic, coulombic, hydrogen bonding and/or magnetic attraction. The surface material and core material may generally comprise the same elemental makeup or chemical composition/component, or the elemental makeup and chemical composition of the surface material may be altered or modified to be different than that of the core material. In most embodiments, the surface material and the core material comprise the same elemental makeup and chemical composition. However, in embodiments where it may be important to detect when the target's useful life has ended or where it is important to deposit a mixed layer of materials, the surface material and the core material may be tailored to comprise a different elemental makeup or chemical composition.

The core material is designed to provide support for the surface material and to possibly provide additional atoms in a sputtering process or information as to when a target's useful life has ended. For example, in a situation where the core material comprises a material different from that of the original surface material, and a quality control device detects the presence of core material atoms in the space between the target and the wafer, the target may need to be removed and retooled or discarded altogether because the chemical integrity and elemental purity of the metal coating could be compromised by depositing undesirable materials on the existing surface/wafer layer. The core material is also that portion of a sputtering target that does not comprise macroscale modifications or microdimples, such as those disclosed in PCT Application Serial No. PCT/US02/06146 and U.S. patent application Ser. No. 10/672,690, both of which are commonly-owned by Honeywell International Inc. and are incorporated herein in their entirety by reference. In other words, the core material is generally uniform in structure and shape.

Sputtering targets may generally comprise any material that can be a) reliably formed into a sputtering target; b) sputtered from the target when bombarded by an energy source; and c) suitable for forming a final or precursor layer on a wafer or surface. Materials that are contemplated to make suitable sputtering targets are metals, metal alloys, conductive polymers, conductive composite materials, conductive monomers, dielectric materials, hardmask materials and any other suitable sputtering material. As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Contemplated metals include those previously described ruthenium-based materials and alloys, which may also include titanium, silicon, cobalt, copper, nickel, iron, zinc, vanadium, zirconium, aluminum and aluminum-based materials, tantalum, niobium, tin, chromium, platinum, palladium, gold, silver, tungsten, molybdenum, cerium, promethium, thorium or a combination thereof. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others.

Thin layers or films produced by the sputtering of atoms from targets discussed herein can be formed on any number or consistency of layers, including other metal layers, substrate layers, dielectric layers, hardmask or etchstop layers, photolithographic layers, anti-reflective layers, etc. In some preferred embodiments, the dielectric layer may comprise dielectric materials contemplated, produced or disclosed by Honeywell International, Inc. including, but not limited to: a) FLARE (poly(arylene ether)), such as those compounds disclosed in issued U.S. Pat. No. 5,959,157, U.S. Pat. No. 5,986,045, U.S. Pat. No. 6,124,421, U.S. Pat. No. 6,156,812, U.S. Pat. No. 6,172,128, U.S. Pat. No. 6,171,687, U.S. Pat. No. 6,214,746, and pending application Ser. Nos. 09/197,478, 09/538,276, 09/544,504, 09/741,634, 09/651,396, 09/545,058, 09/587,851, 09/618,945, 09/619,237, 09/792,606, b) adamantane-based materials, such as those shown in pending application Ser. No. 09/545,058; Serial PCT/US01/22204 filed Oct. 17, 2001; PCT/US01/50182 filed Dec. 31, 2001; 60/345,374 filed Dec. 31, 2001; 60/347,195 filed Jan. 8, 2002; and 60/350,187 filed Jan. 15, 2002; c) commonly assigned U.S. Pat. Nos. 5,115,082; 5,986,045; and 6,143,855; and commonly assigned International Patent Publications WO 01/29052 published Apr. 26, 2001; and WO 01/29141 published Apr. 26, 2001; and (d) nanoporous silica materials and silica-based compounds, such as those compounds disclosed in issued U.S. Pat. No. 6,022,812, U.S. Pat. No. 6,037,275, U.S. Pat. No. 6,042,994, U.S. Pat. No. 6,048,804, U.S. Pat. No. 6,090,448, U.S. Pat. No. 6,126,733, U.S. Pat. No. 6,140,254, U.S. Pat. No. 6,204,202, U.S. Pat. No. 6,208,014, and pending application Ser. Nos. 09/046,474, 09/046,473, 09/111,084, 09/360,131, 09/378,705, 09/234,609, 09/379,866, 09/141,287, 09/379,484, 09/392,413, 09/549,659, 09/488,075, 09/566,287, and 09/214,219 all of which are incorporated by reference herein in their entirety and (e) Honeywell HOSP® organosiloxane.

Wafer or substrate may comprise any desirable substantially solid material. Particularly desirable substrates would comprise films, glass, ceramic, plastic, metal or coated metal, or composite material. In some embodiments, the substrate comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper, copper alloys and its oxides), a polymer-based packaging or board interface such as found in a polyimide-based flex package, lead or other metal alloy solder ball surface, glass and polymers such as polyimides. In more preferred embodiments, the substrate comprises a material common in the packaging and circuit board industries such as silicon, copper, glass, or a polymer. Substrate layers contemplated herein may also comprise at least two layers of materials. One layer of material comprising the substrate layer may include the substrate materials previously described. Other layers of material comprising the substrate layer may include layers of polymers, monomers, organic compounds, inorganic compounds, organometallic compounds, continuous layers and nanoporous layers.

The substrate layer may also comprise a plurality of voids if it is desirable for the material to be nanoporous instead of continuous. Voids are typically spherical, but may alternatively or additionally have any suitable shape, including tubular, lamellar, discoidal, or other shapes. It is also contemplated that voids may have any appropriate diameter. It is further contemplated that at least some of the voids may connect with adjacent voids to create a structure with a significant amount of connected or “open” porosity. The voids preferably have a mean diameter of less than 1 micrometer, and more preferably have a mean diameter of less than 100 nanometers, and still more preferably have a mean diameter of less than 10 nanometers. It is further contemplated that the voids may be uniformly or randomly dispersed within the substrate layer. In a preferred embodiment, the voids are uniformly dispersed within the substrate layer.

The surface provided is contemplated to be any suitable surface, as discussed herein, including a wafer, substrate, dielectric material, hardmask layer, other metal, metal alloy or metal composite layer, antireflective layer or any other suitable layered material. The coating, layer or film that is produced on the surface may also be any suitable or desirable thickness—ranging from one atom or molecule thick (less than 1 nanometer) to millimeters in thickness.

Ruthenium-based alloys and materials and related sputtering targets and deposition sources described herein can be incorporated into any process or production design that produces, builds or otherwise modifies electronic, semiconductor and communication/data transfer components. Electronic, semiconductor and communication components as contemplated herein, are generally thought to comprise any layered component that can be utilized in an electronic-based semiconductor-based or communication-based product. Contemplated components comprise micro chips, circuit boards, chip packaging, separator sheets, dielectric components of circuit boards, printed-wiring boards, touch pads, wave guides, fiber optic and photon-transport and acoustic-wave-transport components, any materials made using or incorporating a dual damascene process, and other components of circuit boards, such as capacitors, inductors, and resistors.

Electronic-based, semiconductor-based and communications-based/data transfer-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic, semiconductor and communication/data transfer products may also comprise a prototype component, at any stage of development from conceptual model to final scale-up mock-up. A prototype may or may not contain all of the actual components intended in a finished product, and a prototype may have some components that are constructed out of composite material in order to negate their initial effects on other components while being initially tested.

### EXAMPLES

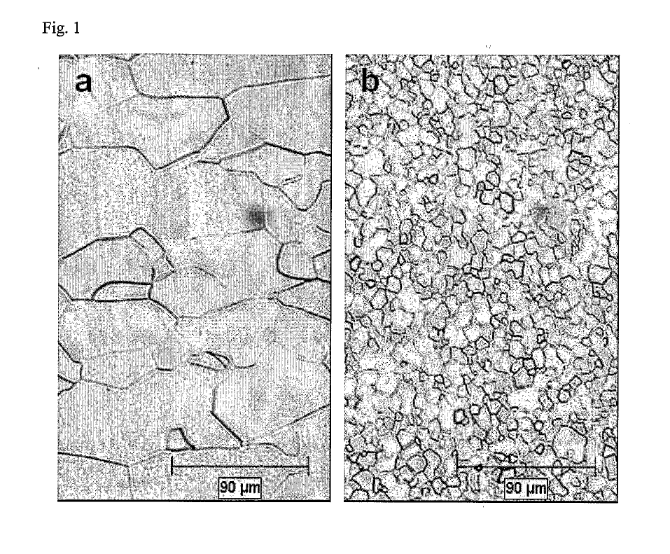

The target materials used in this study were Honeywell 3N grade Ti-5 at. % Zr alloy (US Patent Publication 2003/0132123) hereafter to be designated as TiZr), 3N5 grade Ta, and 3N5 grade Ru. TiZr and Ta targets were made from a hot-rolled metal sheet. Addition of 5 atomic percent Zr to Ti produced a microstructure with an average grain size less than 10 μm. The grain size of hot-rolled Ta was in the range of 30 to 50 μm. FIG. 1 illustrates the optical micrographs of Ta and TiZr alloy. Ti and Zr are in the same group in the periodic table and produce a solid solution with complete miscibility in the entire range of composition. The Ru target was produced via powder metallurgy followed by a final vacuum hot processing. The average grain size in the finished target was ˜85 μm.

Nitride films were prepared by reactive physical vapor deposition (PVD) in an Applied Materials P5500 Endura® system that allowed a deposition of metal, nitride, and copper in tandem without breaking a vacuum. The films were prepared on 200 mm wafers. Specific deposition conditions are addressed with the data. Some Ru films were electrochemically plated with Cu to verify direct plating capability and to evaluate the integral adhesion strength. For the specimens used for Cu diffusion study, a final capping was applied with PVD TaN or chemical vapor deposited (CVD) Si₃N₄ to protect the copper film from oxidation during heat treatment.

Rutherford backscattering spectroscopy (RBS), and scanning electron microscopy (SEM) were employed to determine the ranges of Cu diffusion. Transmission electron microscopy (TEM) was carried out to examine the film microstructure. A Flexus strength gauge was used to measure the film stress. Adhesion strength was evaluated following the ASTM Standard Tape Test Method [8] and by SEM cross-sectional examination. Commendably, the latter SEM method was found to be the most stringent and accurate method in evaluating adhesion strength and determining the extent of Cu diffusion. When a wafer was cleaved for SEM examination, de-bonding occurred if there were weak interfaces. This was visible under the SEM, even if the tape test failed to identify the weakly bonded interface. Film sheet resistance (Rₛ) was measured with a CDE ResMap 4-point electro-probe. Bulk electrical resistivity (ρ) is given by a calibrated ρ=Rₛt formula, where ‘t’ is the film thickness. Film thickness was derived from the weight of the film and specific gravity, and a well-calibrated deposition rate by SEM cross-section method.

### Results and Discussion

### Sputtering Targets

Vickers hardness value of hot-rolled Ti-5 at % Zr alloy was about 210 ksi (1.45 GPa), almost three times higher than the value of Ta (Hv=85 ksi or 0.59 GPa). There was no noticeable change in hardness after thermal annealing for 24 hours at 200° C. for both metals, suggesting that the target would remain stable during sputtering. The 0.2% yield strength was in the range of 68 and 33 ksi for TiZr and Ta, respectively. The improved strength of TiZr alloy was attributable to the solution hardening achieved by the addition of large Zr atoms and associated refinement of grain size.

The mechanical strength and thermal stability of a target is important, particularly for applications that demand high power operation as in long throw self-ionizing-plasma (SIP) systems [13]. Besides the superior mechanical strength, TiZr is lower in cost, lighter in weight, easier to handle, easier to fabricate uniform texture, available in high purity, and less risky in the supply chain. Hexagonal close packed (h.c.p.) TiZr produces a uniform grain texture and thus the variation in deposition rate associated with uneven grain texture has not been observed. On the other hand, it is known that wrought Ta often produces a highly textured or banded target and unacceptable film uniformity [14]. This is mainly because the slip system in b.c.c. Ta tends to leave persistent relics of as-cast grains resulting in banded or textured microstructure after annealing.

### Deposition Performance

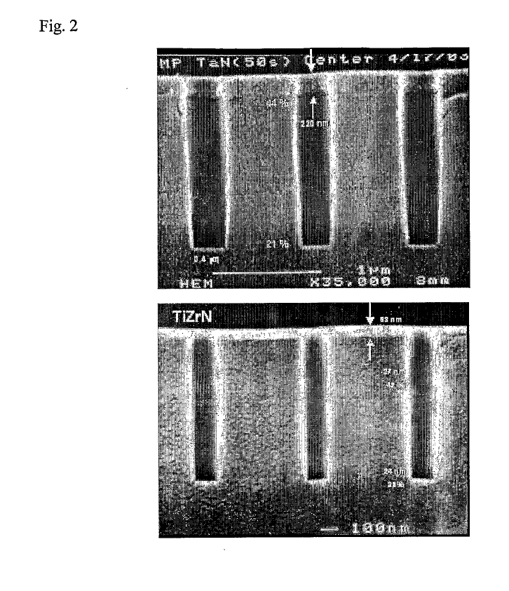

The refinement of grain size is of particular importance, because the target grain size affects not only the mechanical strength but also deposition yield and step coverage. FIG. 2 compares the TaN step coverage for 0.4 μm vias with 4.3 aspect ratio (AR) and the TiZrN step coverage for 0.16 μm vias with AR=5. TaN was deposited reactively with nitrogen in ion metal plasma (IMP) chamber with 4 kW power at 14 mT (25 sccm Ar, 28 sccm N₂). TiZrN film was deposited in a conventional Widebody chamber with 6.5 kW power at 4.3 mT (55 sccm Ar, 75 sccm N₂). It is apparent that the smaller grain size TiZr target delivers visibly better step coverage when one compares the sidewall coverage in regard to the total thickness of the deposited film, in spite of the conventional deposition method and smaller via structure. It has been demonstrated that a finer grain target renders a longer target life due to improved collimation for sputtered atom beams [15, 16]. The physical principle is based on the fact that the atoms sputtered off from the recessed grain boundaries are more focused than those sputtered off from a flat grain surface and that the fraction of collimated beams increases by introducing more grain boundary grooves or by refining grain size. Since focused atom beams have less off-normal beams, deposition yield and step coverage are improved. At the same time, the reduced sidewall deposition extends the shield-life and makes the chamber maintenance less frequent.

### Adhesion

Although both Ta and TaN have shown excellent barrier strength against Cu diffusion, the TaN/Ta bi-layer scheme has been adopted for barrier applications because Ta adhesion to dielectrics (i.e., Si, SiO2) is poor. This is mainly due to the high compressive stress of Ta films as described in the next section. In the bi-layer scheme, metallic Ta has to be added as a glue layer because Cu does not adhere well to nitride.

Extensive characterization of adhesion strength was carried out for various film stacks to understand the nature of adhesion. Only the salient results are summarized in Table I. The main motivation of this work was to identify a barrier scheme that renders good adhesion strength, good barrier strength, and a direct Cu electrochemical plating capability, namely using Ru. The results shows that Ru alone does not provide adequate adhesion strength to dielectrics, Cu does not adhere well to nitride such as TaN and TiZrN, and Ta adhesion to dielectrics is found to be very poor. Both Ta and TiZr do not allow direct Cu electrochemical plating. Therefore, PVD Cu-seed layer was deposited prior to Cu electroplating. For Ru specimens, both PVD and ECP methods were employed for Cu deposition. Both produced virtually identical effect on stress and adhesion. Among all tested matrixes, only TiZr/Ru, TiZrN/Ru, and TaN/Ru bi-layers are identified as acceptable candidates that meet the adhesion and plating requirements. Careful analysis revealed that adhesion strength is largely dictated by the film stress. This analysis is examined in the next section.

TABLE 1
Adhesion strength for various film stacks

| Stacks | Tape Test | Deposition Condition |
|---|---|---|
| Si/SiO₂ >< 25 nm Ru/1 μm Cu | Fail | Ru @ 2 kW/100 C, Cu @ 2 kW/RT |
| Si/SiO₂/20 nm TaN >< 1 μm Cu | Fail | TaN @ 4 kW/100 C, Cu @ 2 kW/RT |
| Si/SiO₂/20 nm TiZrN ><1 μm Cu | Fail | TiZrN @ 4 kW/100 C, Cu @ 2 kW/RT |
| Si/SiO₂ >< 20 nm Ta/10 nm Ru/1 μm Cu | Fail | Ta @ 2 kW/100 C, Ru @ 2 kW/100 C |
| Si/SiO₂/20 nm TaN/10 nm Ru/1 μm Cu | Pass | TaN @ 4 kW/200 C, Ru @ 2 kW/200 C |
| Si/SiO₂/20 nm TiZr/10 nm Ru/1 μm Cu | Pass | TiZr @ 2 kW/100 C, Ru @ 2 kW/100 C |
| Si/SiO₂/20 nm TiZrN/10 nm Ru/1 μm Cu | Pass | TiZrN @ 4 kW/200 C, Ru @ 2 kW/200 C |

The >< symbol represents the failed interface.

### Stress

Stress analysis was carried out using the well-known Stoney's equation for biaxial film stress. Here, σ is an average film stress [Pa] in SI unit, E is the elastic modulus of the substrate [Pa], ν is the Poisson ratio, t is the film thickness [m], h is the substrate thickness [m], and R₁ and R₂ are the radius of curvature [m] before and after film deposition, respectively. In the stress calculations, E/(1−ν)=1.8×10¹¹ Pa is used for (100) Si.

$$σ = \frac{{Eh}^{2}}{( 1 - v ) 6 t} ( \frac{1}{{R}_{2}} - \frac{1}{{R}_{1}} ) .$$

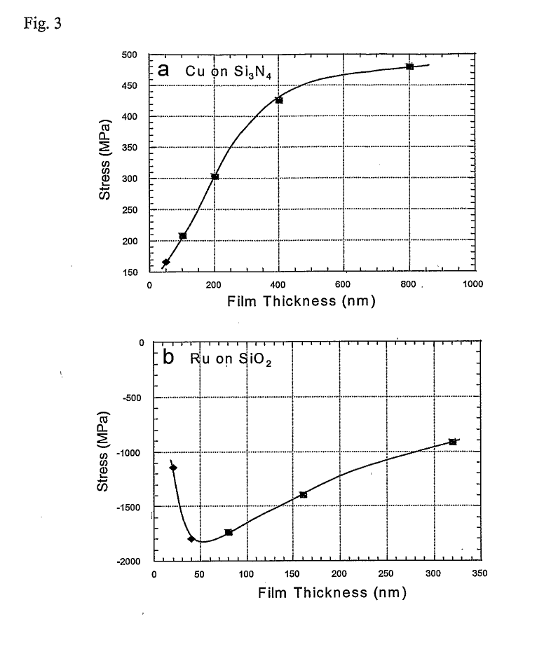

FIG. 3 compares the stress trend for Cu and Ru as a function of film thickness. Cu films were deposited on Si₃N₄ coated Si-wafer at ambient temperature with 2 kW power, because Cu diffuses through SiO₂ and Si. All other films were deposited on SiO₂ coated wafer. Ruthenium films were deposited at 100° C. with 2 kW power. Although copper films show tensile stress as to compressive Ru films, the stress trend is changing from compressive to tensile direction for both Cu and Ru with increasing film thickness. Careful examination of the curves indicates that the tape-pull test adhesion failure occurs when the stress-trend changes from compressive to tensile direction (buckling). This association between ‘buckling’ and ‘adhesion failure’ has been observed consistently in many of our experiments [10]. Although the reversal in stress-trend is not obvious for Cu, evidence indicates that Cu also does deposit as compressive film initially but becomes tensile due to rapid dynamic annealing during deposition. Copper is known to anneal even at room temperature [17]. This point is further elaborated below.

In general, PVD films are compressive in nature due to the shot-peening effect that compresses the film by hammering with particles, here with sputtered atoms. Typical process Ar⁺ ion energy is 400 eV, for example. If a half of this Ar⁺ ion energy transfers to a sputtered atom, the atom would fly out at a speed greater than 10 km/s. When these high-speed atoms bombard the substrate, severe damage is introduced into the film in the form of dislocations, making it compressive. Thus PVD films retain a high density of dislocations. This has been confirmed by TEM. The stored energy in dislocations becomes a driving force for recovery and recrystallization. Such an effect is more pronounced for metals with low melting point such as pure Al and Cu. In alloyed Al, such recovery is substantially impeded due to solute pinning. Although not shown here due to the space constraint, careful examination of stress data indicates that Al and Cu do deposit as compressive films but become tensile due to dynamic recovery during deposition. This can be confirmed by depositing the film at a very low temperature. It is likely that varying degrees of thermally driven recovery occurs in Cu depending upon deposition conditions, particularly when the substrate is subjected to a high temperature plasma environment.

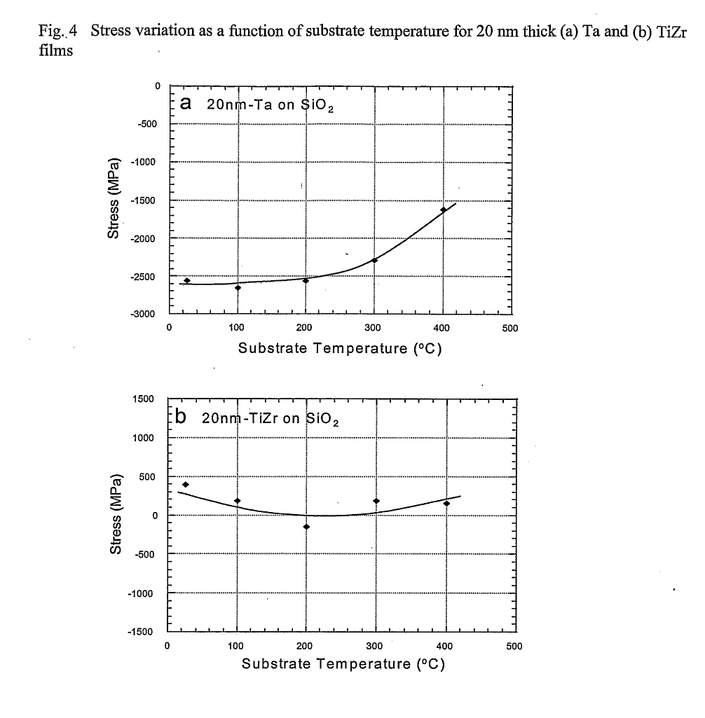

FIG. 4 compares the stress variation as a function of substrate temperature for Ta and TiZr films that were deposited at 4 kW power. All films were 20 nm in thickness. The Ta films showed extremely high compressive stress, over 2000 MPa for most of the temperature range. Despite the high stress, there was no adhesion failure because the stress trend did not change drastically (no buckling effect). However, the adhesion stability was not maintained for highly compressive Ta films when a tensile Cu film was deposited on them as shown next. TiZr films showed more or less neutral stress between −150 and +400 MPa at all temperatures, and showed no adhesion failure as expected, even after Cu deposition.

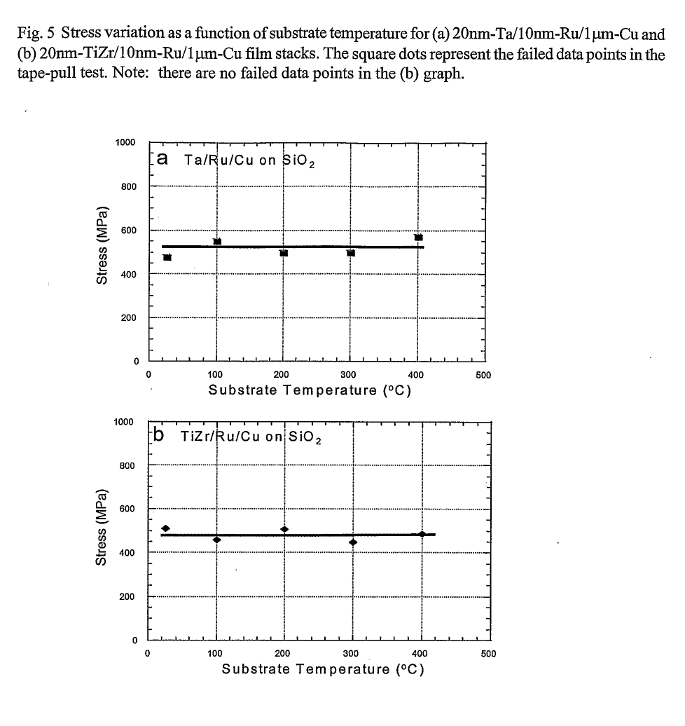

Since an ultimate performance has to be verified for film stacks that are expected in actual devices, triple film stacks were prepared on SiO₂ coated Si-wafers as 20 nm-Ta/10 nm-Ru/1 μm-Cu and 20 nm-TiZr/10 nm-Ru/1 μm-Cu. This will produce a few to several nm thick film, typically vias/trench liner thickness, depending upon the feature size and the PVD method employed. Barrier metal films (Ta, TiZr, Ru) were deposited at 100° C. with 2 kW power, and Cu films at ambient temperature with 2 kW power. FIG. 5 illustrates the stress variation as a function of substrate temperature for Ta/Ru/Cu and TiZr/Ru/Cu film stacks. The final stress values were in the range of 500 MPa for both types of film stacks, suggesting that the thickest Cu film determined the final stress, as can be seen by comparing FIGS. 3 and 5. As expected, the Ta-base barrier films failed the tape-pull test as a result of a reversal in stress state from high compressive to tensile after Cu deposition. On other hand, the neutral TiZr-base barrier stacks maintained excellent adhesion even after Cu deposition. It is clear that the stress is one of the domineering factors for adhesion.

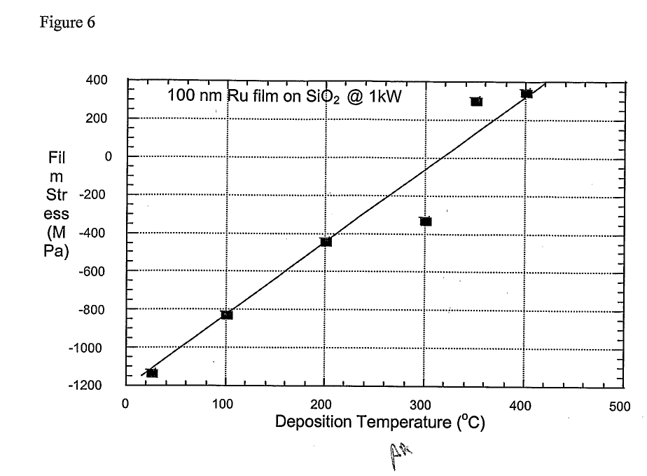

As expected, high melting point nitride films showed very high compressive stress, >3000 MPa compressive for both TaN and TiZrN films deposited below 100° C. Fairly neutral film stress was obtained for TiZrN films deposited between 200° C. and 300° C., whereas TaN film stress remained compressive even at elevated deposition temperature. Despite the high compressive stress, the nitride films showed good adhesion even after Cu deposition. In general, nonmetal-to-nonmetal bonding is found be good as in SiO₂—TaN and SiO₂—TiZrN, for example. The final composite film stress was about 450 MPa tensile for 20 nm-TaN/10 nm-Ru/1 μm-Cu and ˜300 MPa tensile for 20 nm-TiZrN/10 nm-Ru/1 μm-Cu. For Cu electroplating and diffusion barrier strength evaluation, nitride and Ru films were deposited at 200° C. FIG. 6 shows the temperature effects on stress for a ruthenium film on SiO₂. Ruthenium film stress changes from compressive to tensile with increasing deposition temperature.

### Cu Plating

Cu can be electroplated directly, even on 5 nm thin Ru films, without any difficulty. Adhesion tests revealed no delamination issue for either TiZr/Ru/ECP-Cu or TiZrN/Ru/ECP-Cu, suggesting that TiZr/Ru and TiZrN/Ru barriers are compatible for both PVD and ECP Cu as far as the stress is concerned.

In general, metal-to-nonmetal bonding (i.e., Ta—SiO₂) is weaker than metal-to-metal bonding (i.e., Ta—Cu). The inability of plating Cu on Ta or Ti is associated with the persistent oxide layer that prevents adhesion, not the high electrical resistivity. Cu can be plated on Ta and Ti but it does not stick well. Both Cu and Ru form oxide but in less stable state because of their relatively low oxygen affinity compared with Ta and Ti, as compared in Table II. Ruthenium has a low binding energy to oxygen, high standard Gibbs energy for oxide formation, and comparable electronegativity with Cu. Thin copper oxide is known to dissolve readily upon contact with sulfuric acid. In view of Ru being a more noble metal than copper, less stable ruthenium oxide is believed to dissolve easily in acid facilitating Cu plating.

TABLE II
Electronegativity, oxygen bond energy, and Standard Gibbs Energy

| | Electro- | Oxygen | Bond Energy | Oxide | ΔG ° (293 K) |
|---|---|---|---|---|---|
| Element | negativity | Bond | kcal/mole | Form | kcal/mole |
| Cu | 1.9 | Cu-O | 96 | ½Cu₂O | -15.93 |
| Ru | 2.2 | Ru-O | 43 | RuO₂ | -55.37 |
| Ta | 1.6 | Ta-O | 198 | ½Ta₂O₅ | -220.85 |
| Ti | 1.54 | Ti-O | 168 | TiO | -116.06 |

### Barrier Strength

For the evaluation of barrier strength against Cu diffusion, TaN and TiZrN films were deposited at 400° C./6.5 kW/5 mT with 35 sccm Ar and 75 sccm N₂ gas flow rate. RBS analyses revealed that the stoichiometry of metal-to-nitrogen was in the range of Ta_{0.6-0.4}N_{0.4-0.6} and (TiZr)_{0.47-0.60}N_{0.53-0.40}. The Ti/Zr ratio in the film was almost identical to that of the target, and thus sputtering does not appear to alter the target or the film composition. Ta and TiZr metals were deposited at 400° C./2 kW/2.3 mT Ar pressure. Si₃N₄ capping was applied prior to annealing to protect the films from oxidation. Ru film stacks were prepared by depositing 5 nm Ru followed by ˜200 nm Cu with a final TaN capping. Ruthenium was deposited at 100° C. and Cu at ambient temperature.

The barrier strength of the metal was generally lower than that of its counterpart nitride. Both TaN and TiZrN showed excellent barrier strength up to 700° C., while metallic Ta and TiZr showed stability up to 550° C. As a metal, Ru showed exceptional barrier strength up to 700° C. Specific examples are presented below.

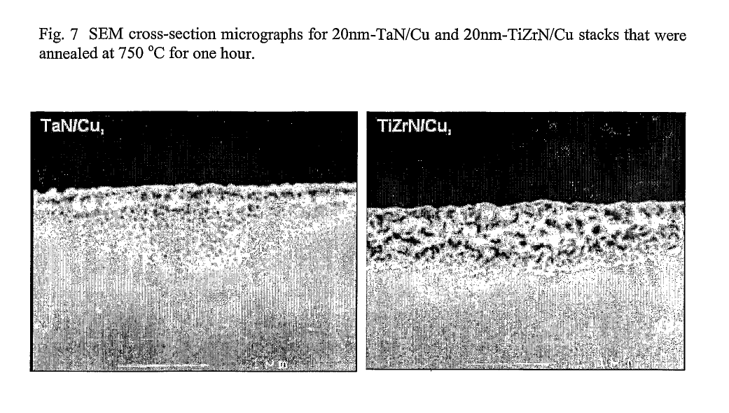

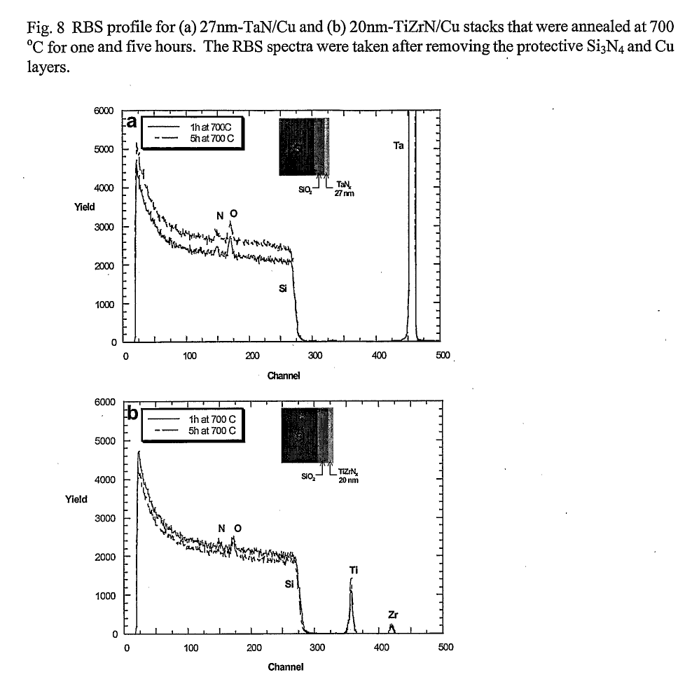

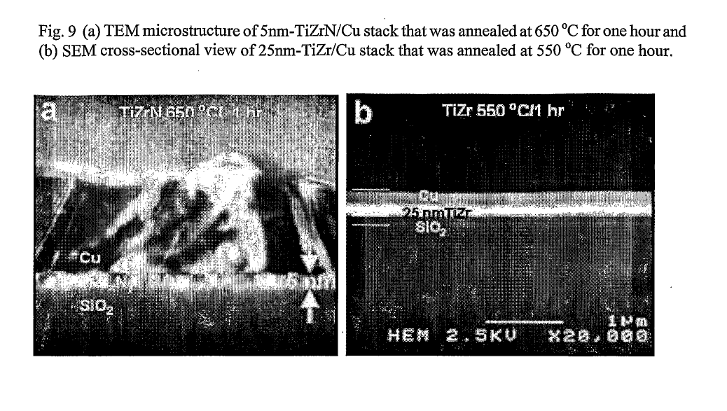

SEM cross-section showed substantial Cu diffusion through TaN and TiZrN after annealing for one hour at 750° C., as shown in FIG. 7. At 700° C., however, there was no indication of Cu diffusion even after 5 hours of annealing. FIG. 8 compares the RBS profiles for the specimens annealed for one and five hours for both TaN and TiZrN. In this case, the Cu layer was removed prior to RBS analysis to ensure that the surface Cu could not affect the analysis. Si₃N₄ and Cu layers were removed by chemically polishing with concentrated HF and diluted HNO₃ acids, respectively. There was no discernible difference in RBS spectra between one and five hour annealed specimens and no trace of Cu in the RBS spectra. FIG. 9 shows the cross-sectional view of the TEM microstructure of TiZrN annealed at 650° C. for one hour and SEM microstructure of TiZr annealed at 550° C. for one hour. In either case, the substrate was clean and there was no hint of Cu diffusion.

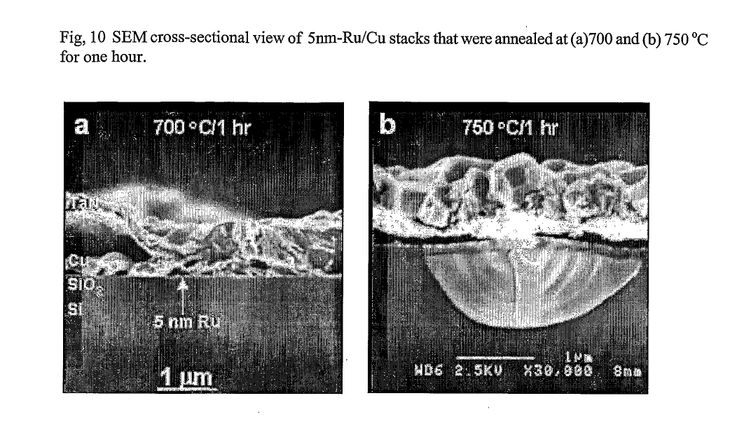

FIG. 10 demonstrates the barrier strength of Ru subjected to 700° C. for one hour. The SEM cross-section revealed no indication of Cu diffusion for the 5 nm thin Ru barrier. For the specimen annealed at 750° C. for one hour, sporadic patches of diffused area were observed. However, there is a significant deterioration of the Ru/Cu interface as can be seen in the SEM cross-section, particularly for the specimen annealed at 750° C. Although there are no known Ru—Cu phases forming at this temperature, it appears that Ru—Cu interaction at elevated temperature leads to intermetallic compound formation weakening the Ru—Cu interface bonding.

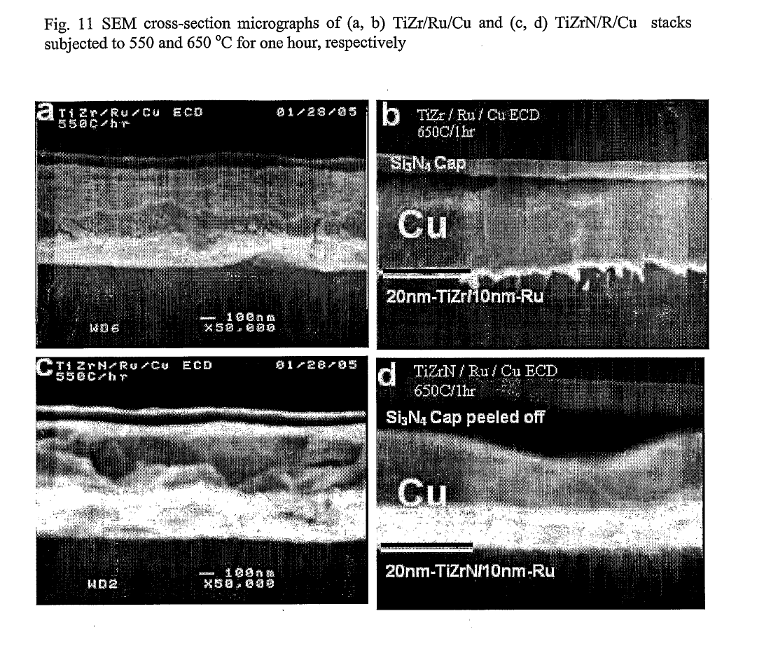

FIG. 11 illustrates the SEM cross-section micrographs for TiZr/Ru/Cu and TiZrN/Ru/Cu stacks that were annealed at 550 and 650° C. for one hour. TiZr/Ru showed excellent barrier strength up to 550° C., no Cu diffusion and no delamination, but there were apparent barrier deterioration at 650° C. Since Ru has shown to block Cu diffusion up to 700° C., the deterioration at 650° C. appears to be associated with the interaction of barrier itself with the substrate, not by the diffusion of Cu. In spite of the deterioration, there was no delamination at Cu/barrier/substrate interfaces. TiZrN/Ru showed excellent adhesion and barrier strength for both temperatures as expected.

Among all the barriers examined thus far, ruthenium, particularly as a metal, is found to be the best diffusion barrier. However, its weak adhesion strength to dielectrics makes it a weak contender. Ta has also shown weak adhesion to dielectrics. In summary, the observed barrier strength is, in increasing order, Ta (550° C.), TiZr (550° C.), TiZr/Ru (550° C.), TaN (700° C.), TiZrN (700° C.), TaN/Ru (700° C.), TiZrN/Ru (700° C.), and Ru (700° C.). In view of adhesion and electroplating, TiZr/Ru, TiZrN/Ru, and TaN/Ru are identified as the three best contenders for barrier application.

### Electrical Resistivity

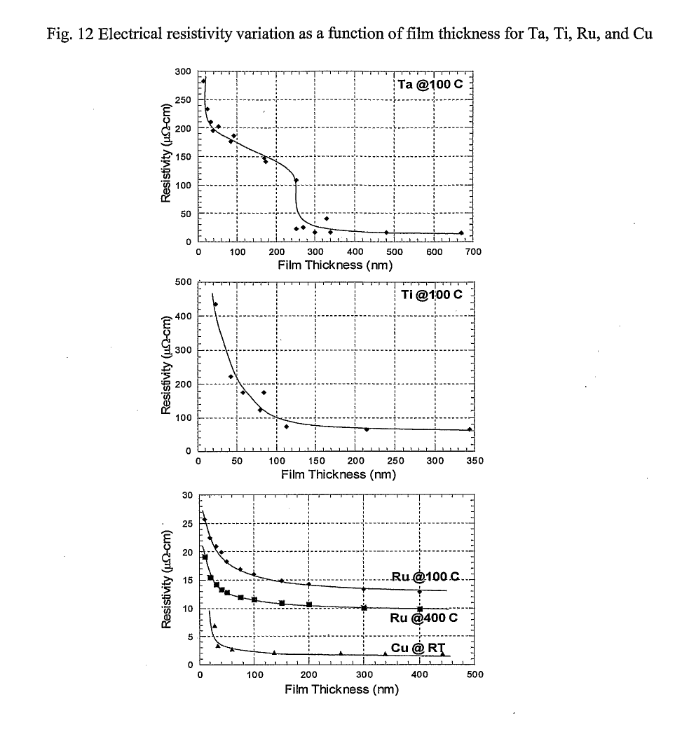

FIG. 12 illustrates the measured electrical resistivity as a function of film thickness for Ta, Ti, Ru, and Cu. The resistivity values for thick films are in the range of 15 μΩ-cm for Ta deposited at 100° C., 64 (Ti, 100° C.), 13 (Ru, 100° C.), 10 (Ru, 400° C.), and 1.9 (Cu, RT). These are somewhat higher compared with the bulk resistivity values of well-annealed metals, Table III. The excess resistivity is attributable to the enhanced electron scattering at fine columnar grain boundaries and dislocations that are typically high in PVD films. The resistivity of 400° C. deposited Ru is lower than that of 100° C. one, as expected.

Electrical resistivity (ρ) increased substantially with decreasing film thickness due to the enhanced electron scattering at the surface and interface. The mean free path length (λ) can be calculated by λ=τV_{F}, where τ is the mean free time between collision and V_{F} is the Fermi velocity. The film and bulk resistivity can be related by ρ_{film}∝ρ_{bulk}(1+λ/t), where t is the film thickness. Detailed computation methods can be found in references [18, 19] and other solid-state physics books. Overall, experimentally measured film resistivity values were considerably higher than theoretically predicted values, again due to the high density of defects in PVD films.

Among the data shown in FIG. 12, Ta showed an unusual bimodal resistivity trend and resistivity values, greater than 200 μΩ-cm for films thinner than 40 nm, almost identical to that of Ti. Thus, it appears that Ta has no advantage in resistivity over Ti for films expected for microelectronic interconnect liner application. It is known that Ta nucleates as tetragonal β-Ta (high resistivity) on SiO₂ and as b.c.c. α-Ta (low resistivity) on TaN [20]. The findings suggest that Ta nucleates initially in β-form on SiO₂ and thereafter grows as α-form as the Ta-film becomes thicker. On the other hand, Ru showed substantially low resistivity, less than 26 μΩ-cm for the 10 nm film. Clearly, the low electrical resistivity is an additional advantage of TiZr/Ru for barrier application. Table III Theoretical mean free path length, and bulk and film resistivity for selected metals

| | λ | ρ (bulk) | ρ (5 nm) |
|---|---|---|---|
| Element | nm | μΩ-cm | μΩ-cm |
| Cu | 39 | 1.67 | 14.96 |
| Ru | 10.2 | 7.13 | 21.68 |
| Ta | 3.81 | 14.1 | 25.55 |
| Ti | 0.83 | 42.1 | 49.1 |

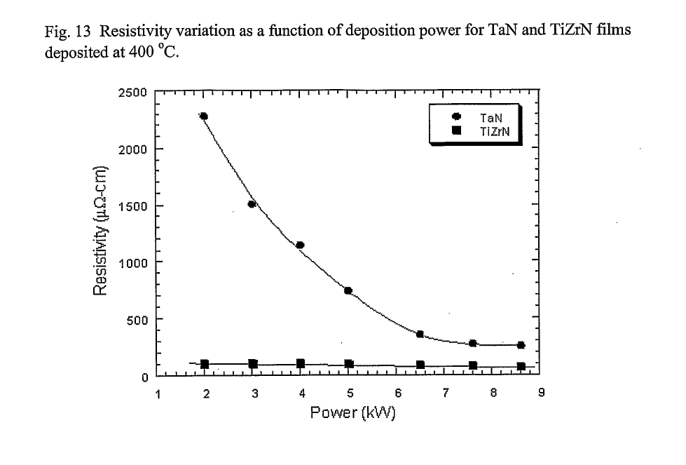

The resistivity values of nitride films were substantially higher than their counterpart metals. FIG. 13 illustrates the resistivity values as a function of deposition power for films thicker than 200 nm. TaN had an unusually high resistivity value of 2280 μΩ-cm at 2 kW, which decreased rapidly to 254 μΩ-cm with increasing power to 8.6 kW. On the other hand, the resistivity of TiZrN films showed not only little variation with the power but much lower values at all power levels, changing merely from 106 to 69 μΩ-cm, with increasing power from 2 to 8.6 kW, respectively. SEM and TEM examination indicated that the unusually high TaN resistivity was associated with low specific gravity and high amorphous fraction that increased with decreasing deposition power. The density increased from 3.8 to 13.9 g/cm³ at increasing deposition powers from 2 to 8.6 kW, with a concomitant decrease in film resistivity.

Thus, specific embodiments and applications of novel ruthenium materials and alloys, their use in vapor deposition or atomic layer deposition and films produced therefrom have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

### REFERENCES

Note: Some references below are directly cited in the body of this application. Those references that are not directly cited in the body of the application are considered those references that contribute generally to the subject matter of the application or provide general knowledge.
1. Oliver Chyan et al., Abs. 595, 20th Meeting, The Electrochemical Society, Inc., (2003).
2. Lane, et al., U.S. Pat. No. 6,787,912 (2004).
3. Fred Fishburn, U.S. Pat. No. 6,787,833 (2004).
4. Eugene P. Marsh, U.S. Pat. No. 6,787,449 (2004).
5. Dong-Soo Yoon and Jae Sung Rho, IEEE Electron Device Letters, 23(4) (2003) p. 176.
6. A. H. Fisher, A. von Glaswo, S. Penka, and F. Unger, Proc. IITC 2003, EEEE Electron Devices Society (2003) 253.
7. D. Edelstein, C. Uzoh, C. Cabral, Jr., P. DeHaven, P. Buchwalter, A. Simon, E. Cooney, S. Malhotra, D. Klaus, H. Rathore, B. Agarwala, and D. Nguyen, Proc. IITC 2001, IEEE Electron Devices Society (2001) 9.
8. Barry L. Chin, Gongda Yao, Peijun, Jianming Fu, and Liang Chen, Semiconductor International, 24 (2001) 107.
9. Ishita Goswami and Ravi Laxman, Semiconductor International, 27(5) (2004) p. 49.
10. Eal Lee, Nicole Truong, Nancy Iwamoto, Werner Hort, Mike Pinter, and Janine Kardokus, submitted to IITC 2005.
11. Paul Besser, Amit Marathe, Larry Zhao, Matthew Herrick, Cristiano Capasso, Hisao Kawasaki. Technical Digest—International Electron Devices Meeting (2000), pp. 119-122.
12. K. Y. Lim, Y. S. Lee, Y. D. Chung, I. W. Lyo, C. N. Whang, J. Y. Won, H. J. Kang. Appl. Phys. A 70 (2000) p. 431.
13. Cross-cut tape test by ASTM D3359-95, Annual Book of ASTM Standards, Vol. 06.01.
14. Christopher A. Michaluk, J. Electronic Materials, 31 (1) (2002) 2-9.
15. Eal Lee, Cara Hutchison, Anil Bhanap, Nicole Truong, Robert Prater, Mike Pinter, and Wuwen Yi, Advances Electronics Manufacturing Technology, www.Vertilog.com, V-EMT 1:16 (2004).
16. Eal Lee, Nicole Truong, Bob Prater, Wuwen Yi, and Janine Kardokus, submitted to J. Vac. Sci. Technol. B
17. Qing-Tang Jiang and Michael E. Thomas, J. Vac. Sci. Technol. B 19(3) (2001) p. 762.
18. Frank J. Blatt, “Physics of Electronic Conduction in Solids,” McGraw-Hill, New York 1968
19. S. O. Kasap, “Principles of Electronic Materials and Devices,” McGraw Hill, New York, 2002.
20. Martin Traving, Günther Schindler, Gernot Steinlesberger, Werner Steinhögl, and Manfred Engelhardt, Semiconductor International 26(8) (2003) p. 73.

We claim:

1. An alloy for use in vapor deposition or atomic layer deposition, comprising ruthenium and at least one element from group IV, V or VI of the Periodic Chart of the Elements or a combination thereof.

2. The alloy of claim 1, wherein the at least one element comprises Ta, Ti, Zr, Hf, V, Nb, Mo, W or a combination thereof.

3. The alloy of claim 1, further comprising silicon, oxygen, nitrogen or a combination thereof.

4. A sputtering target comprising the alloy of claim 1.

5. The alloy of claim 1, wherein vapor deposition comprises physical vapor deposition or chemical vapor deposition.

6. A film produced using the alloy of claim 1.

7. The film of claim 6, wherein the film is a copper diffusion barrier film.

8. The film of claim 7, wherein the film is utilized for seedless copper electroplating.

9. The film of claim 6, wherein the film has improved adhesion as compared to films produced from non-ruthenium-based alloys.

10. A component formed by the sputtering target of claim 4.

11. A component incorporating the film of claim 6.

12. A layered material, comprising:
at least one layer that includes a ruthenium-based material or ruthenium-based alloy; and
at least one layer that includes at least one element from group IV, V or VI of the Periodic Chart of the Elements or a combination thereof.

13. The material of claim 12, wherein the at least one element comprises Ta, Ti, Zr, Hf, V, Nb, Mo, W or a combination thereof.

14. The material of claim 12, wherein the at least one layer that includes at least one element from group IV, V or VI of the Periodic Chart of the Elements or a combination thereof further comprises silicon, oxygen, nitrogen or a combination thereof.

15. The layered material of claim 12, wherein the material is a copper diffusion barrier film.

16. The layered material of claim 15, wherein the material is utilized for seedless copper electroplating.

17. The layered material of claim 16, wherein the material has improved adhesion as compared to layered materials produced from non-ruthenium-based materials.

18. The layered material of claim 12, wherein each of the at least one layer that includes a ruthenium-based material or ruthenium-based alloy is less than about 300 Å thick.

19. The layered material of claim 18, wherein each of the at least one layer that includes a ruthenium-based material or ruthenium-based alloy is less than about 200 Å thick.

20. The layered material of claim 19, wherein each of the at least one layer that includes a ruthenium-based material or ruthenium-based alloy is less than about 150 Å thick.

21. The layered material of claim 12, wherein each of the at least one layer that includes at least one element from the group IV, V or VI of the Periodic Chart of the Elements is less than about 300 Å thick.

22. The layered material of claim 21, wherein each of the at least one layer that includes at least one element from the group IV, V or VI of the Periodic Chart of the Elements is less than about 200 Å thick.

23. The layered material of claim 22, wherein each of the at least one layer that includes at least one element from the group IV, V or VI of the Periodic Chart of the Elements is less than about 150 Å thick.

24. The layered material of claim 12, comprising at least one additional layer of material.

25. The layered material of claim 24, wherein the at least one additional layer of material comprises copper, a copper alloy or a combination thereof.

26. A component incorporating the layered material of claim 12.
